(19) United States
(12) Patent Application Publication
(10) Pub. No.: US 2023/0069041 A1
(43) Pub. Date: Mar. 2, 2023

(54) DETECTION OF INCIPIENT FAILURES IN INSTRUMENT TRANSFORMERS

(71) Applicant: Schweitzer Engineering Laboratories, Inc., Pullman, WA (US)

(72) Inventor: Md Arif Khan, Pullman, WA (US)

(73) Assignee: Schweitzer Engineering Laboratories, Inc., Pullman, WA (US)

(21) Appl. No.: 17/809,666

(22) Filed: Jun. 29, 2022

Related U.S. Application Data
(60) Provisional application No. 63/237,329, filed on Aug. 26, 2021.

(51) Int. Cl. G01R 31/62; H02J 3/00; H02J 13/00; G01R 19/165

(52) U.S. Cl. CPC G01R 31/62; H02J 3/0012; H02J 13/00002; G01R 19/1659

(57) ABSTRACT

Methods and devices are provide for determining a failure in a potential transformer and identifying a phase of the potential transformer exhibiting failure. The failures may be incipient failures. Detecting the failure may include determining voltage magnitudes and angles; determining phase-errors; determining phase-phase errors; and determining an uncorrelated phase using the phase-phase errors. The devices and methods may provide an alarm or indication of the phase exhibiting the potential transformer failures. Post processing may be performed to optimize the time and amount of provided alarms or indications. The voltage angles and magnitudes may be provided by the potential transformers being monitored.

### RELATED APPLICATION

This application claims priority from and benefit of U.S. Provisional Application Ser. No. 63/237,329 filed on 26 Aug. 2021 naming Md Arif Khan as the inventor, titled “Detection of Incipient Failures in Instrument Transformers” which is incorporated herein by reference in its entirety.

### TECHNICAL FIELD

This disclosure relates to detection of incipient failures in instrument transformers such as potential transformers. This disclosure further relates to detecting incipient failures using uncorrelated phase errors.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates a simplified one-line diagram of an electric power delivery system including an intelligent electronic device (IED) for monitoring and protection.

FIG. 2 illustrates a simplified block diagram of an IED obtaining voltage signals from a potential transformer.

FIG. 3 illustrates a simplified block diagram for determining a phase exhibiting incipient failures in a potential transformer.

FIG. 4 illustrates a logic diagram for determining a phase exhibiting incipient failures in a potential transformer.

FIG. 5 illustrates a simplified block diagram for pre-processing voltage signals for incipient failure detection.

FIG. 6 illustrates a simplified block diagram for alarm signal generation using detected incipient failures.

FIG. 7 illustrates a method for determining incipient failures in a potential transformer.

FIGS. 8A, 8B, 8C, and 8D illustrate plots from an example of voltage signals and incipient failure detection in accordance with several embodiments herein.

### DETAILED DESCRIPTION

Safe, reliable, and economical operation of electric power delivery systems requires close monitoring of operating conditions using current and voltage signals collected from various equipment. Current and voltage signals may be obtained using instrument transformers to obtain samples from the electric power system equipment that may be used by various monitoring devices. The accuracy of voltage measurements is critical for power system protection, operation, and control. For example, distance relays can overreach, false trip, or make incorrect directional decisions when they operate on erroneous voltage measurements. Erratic voltage measurements can influence the voltage and frequency algorithms of protective relays and phasor measurement units and can cause errors in voltage phasor estimates. Voltage magnitude errors can cause false alarms in the voltage-monitoring modules in control centers. Voltage measurement errors can result in shifts in the voltage angles, which can create false alarms in the phase angle difference and system stress-monitoring modules that are typically used in power system operation and control centers.

Voltage measurement errors can emanate from an aging potential transformer, failing fuse, faults in the voltage measurement circuit, or the like. Material degradation, reduction in dielectric strength, and corroded spark gaps in a coupling-capacitor voltage transformer (CCVT) can result in slight errors in secondary voltage, corrupted voltage signals, or a total loss of voltage. Potential transformers often exhibit incipient failures before complete failure. The incipient failures may be present for an extended time period before complete failure. The advantages of early detection are substantial. Detecting a failing component late can result in urgent replacement scheduling, which is inefficient and increases maintenance costs. Furthermore, if the detection method only detects outright failure, the result can be costly equipment damage and injury to personnel. Early detection and efficient repair scheduling can reduce the duration of time that a potential transformer is out of service and the associated duration when certain protection functionality is disabled.

Accordingly, what is needed is improved detection of incipient failures in potential transformers. Presented herein are systems and methods for detection of incipient failures in potential transformers using signals from the potential transformers.

The embodiments of the disclosure will be best understood by reference to the drawings, wherein like parts are designated by like numerals throughout. It will be readily understood that the components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor need the steps be executed only once, unless otherwise specified.

Several aspects of the embodiments described may be implemented as software modules or components or elements. As used herein, a software module or component may include any type of computer instruction or computer executable code located within a memory device and/or transmitted as electronic signals over a system bus or wired or wireless network. A software module or component may, for instance, comprise one or more physical or logical blocks of computer instructions. Software modules or components may comprise disparate instructions stored in different locations of a memory device, which together implement the described functionality of the module. Indeed, a module or component may comprise a single instruction or many instructions, and may be distributed over several different code segments, among different programs, and across several memory devices. Some embodiments may be practiced in a distributed computing environment.

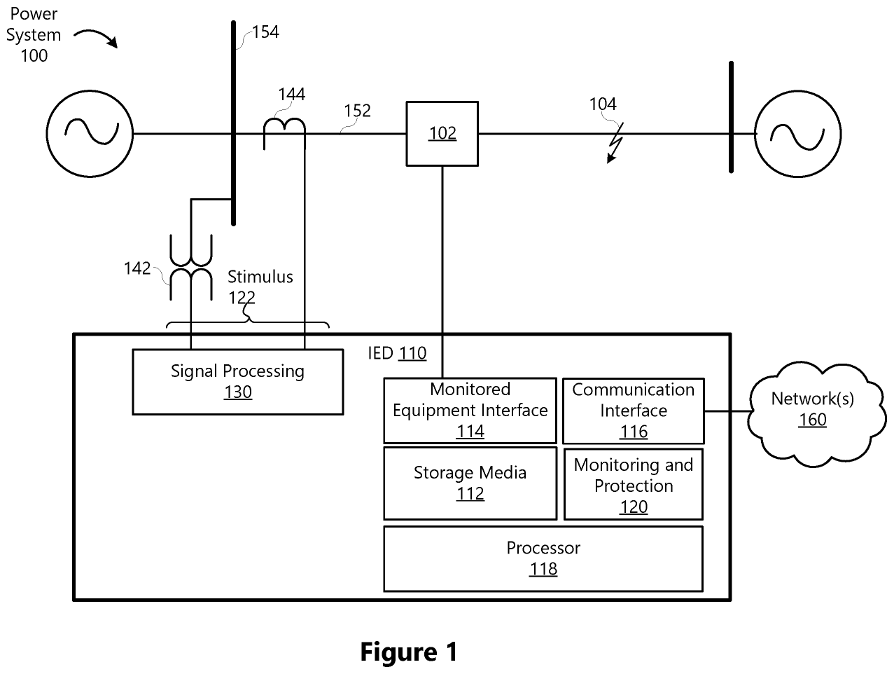

FIG. 1 illustrates a one-line diagram of an electric power delivery system 100 monitored by an IED 110 that provides electric power system monitoring and protection. The IED may provide protective actions, such as opening a circuit breaker 102 upon detection of a fault 104 (using, e.g., overcurrent, distance, and/or directional protection elements). In various embodiments the IED 110 may be a protective relay providing protective functions to the electric power delivery system 100. In various other embodiments, the IED 110 may be a digital fault recorder for recording electric power delivery system 100 operating conditions and alarming upon detection of certain conditions including system faults and equipment failures. IED 110 may comprise and/or be implemented in conjunction with a computing device. IED 110 may include a processor 118, which may comprise one or more general purpose processors, special purposes processors, ASICs, programmable logic elements (e.g., FPGAs), or the like. The IED 110 may further comprise non-transitory machine-readable storage media 112, which may include one or more disks, solid-state storage (e.g., Flash memory), optical media, or the like. Storage media 112 may be packaged individually, packaged with the processor 118, or combinations thereof.

The IED 110 may be communicatively coupled to one or more networks 160 via one or more communication interfaces 116. The networks 160 may include special-purpose networks for monitoring and/or controlling the electrical power system 100 (e.g., SCADA networks, or the like). The networks 160 may further include general purpose communication networks, such as a TCP/IP network, or the like. The communication interface 116 may include wired and/or wireless communication interfaces (e.g., serial ports, RJ-45, IEEE 802.11 wireless network transceivers, etc.). In some embodiments, the IED 110 may include human-machine interface (HMI) components (not shown), such as a display, input devices, and so on.

The IED 110 may include monitoring and/or protection functions in a monitoring and protection module 120 that may be embodied as instructions stored on computer-readable media (such as storage media 112) that, when executed on the processor 118, cause the IED 110 to perform monitoring and protection operations. The protection operations may include, for example, overcurrent, directional, distance, underfrequency, and other protection operations using signals provided by the signal processing 130. The monitoring and protection 120 may also include monitoring of instrument transformers using signals provided by the signal processing 130.

The signal processing 130 may include filtering, delays, and the like to filter out distortions and transients with frequencies different than the fundamental frequency of the power system. The signal processing 130 may process electrical power system signals in accordance with the several embodiments herein for use by the monitoring and protection operations of the IED 110. The signal processing 130 may be implemented in hardware, software (firmware), or a combination. For example, the signal processing 130 may include analog-to-digital (A/D) converters to sample the analog stimulus 122 and provide digitized analogs. The signal processing 130 may include circuitry and/or computer instructions for execution by the processor 118 to filter the digitized analogs and provide filtered samples for monitoring and protection operations in accordance with the various embodiments described herein.

The IED 110 may be communicatively coupled to the power system 100 through current transformer(s) 144 and potential transformer(s) 142. That is, the stimulus 122 may be received from the electric power system 100 via instrument transformers. The stimulus 122 may be received directly via the measurement devices described above and/or indirectly via the communication interface 116 (e.g., from another IED or other monitoring devices such as merging units (not shown) in the electrical power system 100). The stimulus 122 may include, but is not limited to: current measurements, voltage measurements, and the like.

Furthermore, the IED 110 may include a monitored equipment interface 114 in electrical communication with monitored equipment. As illustrated, the monitored equipment interface 114 is in communication with a circuit breaker 102. The monitored equipment interface 114 may include hardware for providing a signal to the circuit breaker 102 to open and/or close in response to a command from the IED 110. For example, upon detection of a fault, the IED 110 may signal the monitored equipment interface 114 to provide an open signal to the appropriate circuit breaker 102, thus effecting a protective action on the electric power delivery system. In certain embodiments, the protective action may be effected by additional or separate devices. For example, upon determination of the fault, the IED 110 may signal other devices (using, for example, the network 160, or signaling another device directly) regarding the fault, which other devices may signal a breaker to open, this effecting the protective action on the electric power delivery system.

The signal processing 130 in accordance with several embodiments described herein provides an output signal that maintains integrity and speed even during transient conditions. Generally, the signal processing 130 provides a band-pass filter to filter out distortions and transients with frequencies different than the fundamental frequency of the source signal.

Typically, such filters use a full-cycle window. Meaning the filter's window length equals the period of the fundamental frequency component, typically 1/50 Hz or 1/60 Hz (20 ms or 16.67 ms, respectively). To keep accuracy as the system frequency changes, these implementations measure frequency and apply adequate correction: either explicit, or by adjusting the sampling rate in such a way that the filtering system maintains the same nominal number of samples per cycle, even as the cycle slightly changes with the system frequency.

Typically, microprocessor-based relays operate on phasors. A phasor represents a sine wave signal with its magnitude and angle relative to some arbitrary angle reference, or with the real and imaginary parts relative to some arbitrary frame of reference. A pair of finite impulse response (FIR) filters can be used to obtain the phasor's real and imaginary parts. These filters are often referred to as orthogonal filters. For example, a sine and cosine filter can be used as a pair of orthogonal filters (the Fourier method), or a cosine and a cosine delayed by 0.25 of a cycle can be used (the cosine method) to obtain phase magnitude and angle of the voltage and current signals. As will be described hereafter, the voltage phase magnitudes and angles may be used to detect incipient failures in a potential transformer.

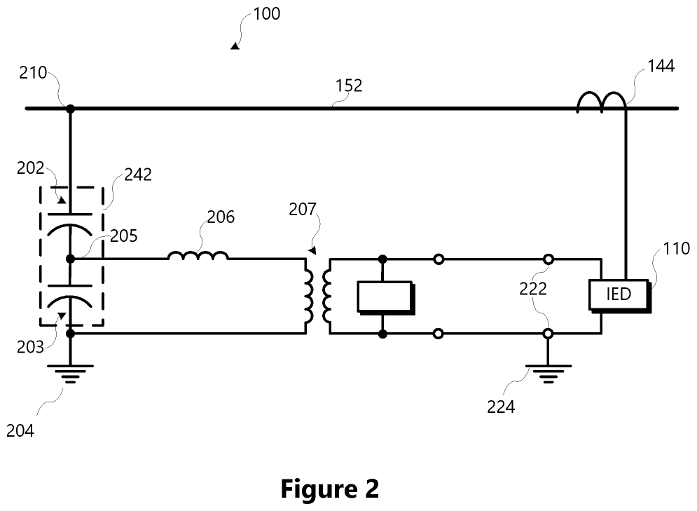

FIG. 2 illustrates a simplified block diagram of an IED 110 for monitoring an electric power delivery system 100 using current signals from a CT 144 and voltage signals from a coupling-capacitor voltage transformer (CCVT) 242. It should be noted that the embodiments herein may be used to detect failures in many types of potential transformers including, for example, magnetic transformers, CCVTs, optical transformers, and the like. The CCVT 242 of FIG. 2 is illustrated as one example of a possible implementation of the embodiments disclosed herein.

A capacitor stack that includes a high-voltage portion 202 and a low voltage portion 203 is connected between a primary voltage terminal 210 and a substation ground 204. The capacitor stack creates a capacitive voltage divider and produces an intermediate voltage at the tap terminal 205. In various embodiments, the primary voltage may be 110 kV and above, and may include 750 kV and 1 MV networks. The intermediate voltage may be in the range of 5-30 kV. A step-down transformer 207 further steps down the intermediate voltage to a standard secondary voltage at the output CCVT terminals 222. The standard secondary voltage may be in the range of 60-250 V in various embodiments.

A direct connection of a step-down transformer to a capacitor stack may introduce an angle measurement error. To reduce that error, a tuning reactor 206 may be connected in series between the intermediate voltage terminal 205 in the capacitive divider and the step-down transformer 207.

Various other forms of potential transformers may be used, and an IED 110 may be connected thereto accordingly. Separate potential transformers may be used to obtain voltage measurements from different phases of the electric power delivery system. For example, in a three-phase electric power delivery system, voltage measurements from a particular equipment may be obtained using three potential transformers, each associated with a different one of the three phases. The embodiments herein may not only detect incipient failures in potential transformers, but also determine the phase in which the incipient failures occur.

When there is an impending failure in the potential transformer circuit, such as a degrading fuse, data show that it tends to generate relatively small, random, and intermittent excursions of the measurements from a steady state. When one phase is failing and the others are not, these excursions are present only in the measurements from the failing phase. When multiple phase circuits start to develop an impending failure, the excursions are likely to be uncorrelated between one phase and another at a particular instant. The detection techniques described herein is used to detect such an intermittent, phase-to-phase-uncorrelated response, in addition to random phase-angle changes during the incipient stage.

In general, the embodiments herein detect incipient failures in potential transformers by calculating phase errors in voltage magnitudes and angles; calculating phase-phase errors in voltage magnitudes and angles; and, comparing the phase-phase errors to determine an uncorrelated phase as the phase with an incipient failure. For this, the detection may include a pre-processing of voltage measurements, failure detection in the incipient stage from the preprocessed signals, and postprocessing of the detection results for alarm generation that suits a control room environment.

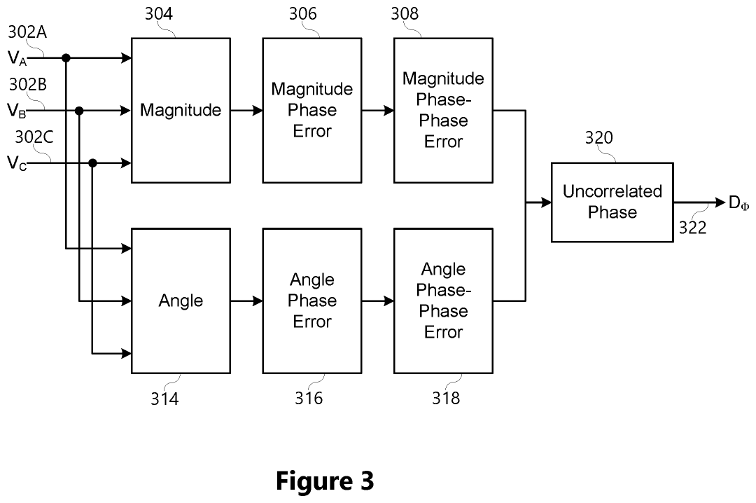

FIG. 3 illustrates a general block diagram of incipient failure detection in accordance with several embodiments herein. Phase voltage signals V_{A} 302A, V_{B} 302B, and V_{C} 302C are obtained (using, for example, signal processing of signals from a potential transformer, or signals from a merging unit). Magnitudes of the three phase voltages are calculated 304; and phase angles of the three phase voltages are calculated 314. As indicated above, these may be the magnitudes and angles represented by voltage phasors. The phase errors of the voltage magnitudes are calculated 306 and the phase errors of the voltage angles are calculated 316. The phase errors may represent a difference between the magnitude or angle and a filtered magnitude or angle. The phase errors, as described in more detail below, may be calculated to remove slowly varying ambient process and phase imbalance, and to enhance random voltage drops that may be due to potential transformer failure.

The phase errors are compared to generate voltage magnitude phase-to-phase errors 308 and voltage angle phase-to-phase errors 318. The phase-to-phase errors may be generated by calculating a difference between each phase pair for the magnitudes and for the angles. At a particular instant, if some phase is failing while the others are healthy, the phase-to-phase errors clearly show the failing signature. The voltage drop in all three phases is treated as a typical operation in the power system, such as the starting of a large industrial motor, because the design assumes no common-cause failure modes. Therefore, correlated changes in all three phases are removed in the phase-to-phase error signals.

Finally, the phase-to-phase errors are compared to determine an uncorrelated phase 320. The uncorrelated phase 322 is determined to be a phase exhibiting an incipient failure Do. The uncorrelated phase may be determined as the phase that exhibits both a magnitude phase-to-phase error above a magnitude threshold and an angle phase-to-phase error above an angle threshold.

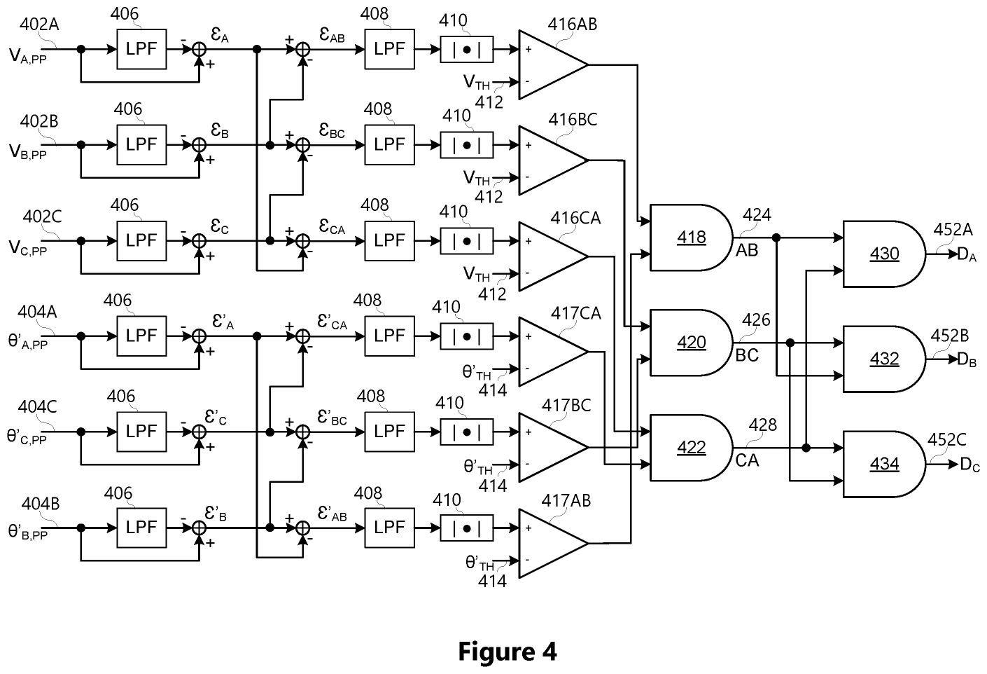

FIG. 4 illustrates a logic diagram for determining a phase exhibiting incipient failures in a potential transformer in accordance with an embodiment. Voltage magnitudes and voltage angles for each phase of the multiple-phase electric power delivery system are used. In accordance with several embodiments, pre-processed voltage magnitudes for each phase V_{A,PP} 402A, V_{B,PP} 402B, V_{C,PP} 402C, and pre-processed voltage angles θ′_{A,PP} 404A, θ′_{B,PP} 404B, θ′_{C,PP} 404C, are used for determining phase voltage incipient failures. In accordance with various embodiments, the derivatives of voltage angles are determined in pre-processing, while in other embodiments no derivatives are calculated. Accordingly, in the illustrated embodiment, the pre-processed voltage angles 404A-C and select other quantities are calculated using derivatives and are illustrated with the prime designation. Embodiments of pre-processing that may be used are described in further detail below.

Each of the pre-processed phase voltage magnitudes 402A-C and pre-processed phase voltage angles 404A-C may be filtered using a low-pass filter (LPF) 406. The low-pass filter 406 may include infinite impulse response (IIR) to estimate a slowly-varying, time-delayed ambient response of the system. Phase error signals may be calculated as differences between the pre-processed signal and filtered pre-processed signals. In certain embodiments, for each of the six input signals 402A-C and 404A-C, the filtered signal is subtracted from the corresponding pre-processed signal to produce phase error signals. That is, each of the filtered pre-processed phase voltage magnitudes may be subtracted from the pre-processed phase voltage magnitudes 402A-C to produce voltage magnitude phase error signals ε_{A}, ε_{B}, and ε_{C}. Similarly, each of the filtered pre-processed voltage angles are subtracted from the pre-processed voltage angles 404A-C to produce voltage angle phase error signals ε′_{A}, ε′_{B}, and ε′_{C}. Accordingly, slowly varying ambient processes are removed from the voltage magnitudes and angles. Phase imbalances are likewise removed. Furthermore, the signature of random voltage drops due to the failure in a potential transformer circuit is enhanced.

The voltage magnitude phase errors and voltage angle phase errors may be then combined to produce phase-phase error signals. In certain embodiments, differences between each phase error signal may be calculated to produce phase-phase error signals. In one embodiment, differences between each voltage magnitude phase error are calculated to produce voltage magnitude phase-phase errors; and differences between each voltage angle phase error are calculated to produce voltage angle phase-phase errors.

As illustrated, A-phase voltage magnitude error ε_{A} is subtracted from C-phase voltage magnitude error ε_{C} to produce the C-A phase-phase voltage magnitude error ε_{CA}. The B-C phase-phase voltage magnitude error ε_{BC} and the A-B phase-phase voltage magnitude error ε_{AB} are likewise calculated. Similarly, the A-phase voltage angle error ε′_{A} is subtracted from the B-phase voltage angle error ε′_{B} to produce the A-B phase-phase voltage angle error ε′_{AB}. The B-C phase-phase voltage angle error ε′_{BC} and the C-A phase-phase voltage angle error ε′_{AB} are likewise calculated.

At a particular instant, if some phase is failing while the others are healthy, the phase-phase errors may be used to show a signature of the failing phase. The voltage drop in all three phases is treated as a typical operation in the power system, such as the starting of a large industrial motor. The embodiments herein may assume no common-cause failure modes. Accordingly, correlated changes in all three phases are removed in the phase-phase error signals.

The phase-phase error signals ε_{AB}, ε_{BC}, ε_{CA}, ε′_{CA}, ε′_{BC}, and ε′_{AB} may include noise. In accordance with various embodiments, the phase-phase error signals may be filtered using, for example, LPF 408. The LPF may include a finite impulse response (FIR) filter for a moderate level of smoothing. In various other embodiments, an IIR filter may be used. An IIR filter may be designed with approximately linear phase response.

The absolute values 410 of each of the filtered phase-phase error signals may be calculated. The absolute values may be compared to predetermined thresholds. The absolute values of the voltage magnitude phase-phase errors may be compared to a voltage magnitude threshold VTH 412; and the voltage angle phase-phase errors may be compared to a voltage angle threshold θ′_{TH} 414. For each phase-phase error pair that exceeds the threshold, the comparator will assert a binary signal corresponding to a possible failure in one or more of the potential transformers associated with the phases of the phase-phase error pair. That is, comparator 416AB asserts when the absolute value of the filtered voltage magnitude A-B phase-phase error signal exceeds the threshold VTH 412, indicating that a potential transformer of phase A and/or phase B may be experiencing a failure. Similarly, comparator 416BC asserts for the comparison for the B-C phase-phase voltage magnitude pair; and comparator 416CA asserts for the comparison for the CA phase-phase voltage magnitude pair.

Likewise for the phase-phase angle pairs, comparator 417CA asserts when the absolute value of the filtered voltage angle C-A phase-phase error signal exceeds the threshold θ′_{TH} 414, indicating that a potential transformer of phase C and/or phase A may be experiencing a failure. Similarly, comparator 417BC asserts for the comparison for the B-C phase-phase voltage angle pair; and comparator 417AB asserts for the comparison for the A-B phase-phase voltage angle pair.

When there is a failure in a potential transformer phase circuit, the failure likely manifests in both the voltage magnitude and the voltage angle measurements from that phase. This is because the failure is represented as distortion in the instantaneous voltage signal. If, however, the signal remains sinusoidal, but changes in amplitude, then the potential transformer magnitude changes and the phase angle does not change. This type of distortion is not consistent with a failing potential transformer signal.

The failing phase potential transformer may be identified from the phase-phase digitals provided by the comparators 416AB, 416BC, 416CA, and 417CA, 417BC, and 417AB. Generally, if a common phase is represented in each of the asserted signals, then that phase may be determined as the uncorrelated phase associated with a failing potential transformer. Following the illustrated embodiment, an uncorrelated phase-phase pair is identified. As illustrated, AND gate 418 asserts signal 424 when both the AB voltage magnitude phase-phase error comparator 416AB asserts AND the AB voltage angle phase-phase error comparator 417AB asserts. Similarly, AND gate 420 asserts signal 426 when both the BC voltage magnitude phase-phase error comparator 416BC asserts AND the BC voltage angle phase-phase error comparator 417BC asserts. Finally, AND gate 422 asserts signal 428 when both the CA voltage magnitude phase-phase error comparator 416CA asserts AND the CA voltage angle phase-phase error comparator 417CA asserts.

In the next step, the uncorrelated phase is determined using the uncorrelated phase-phase pairs. As illustrated, AND gate 430 asserts A-phase detection signal D_{A} 452A when both the AB uncorrelated phase-phase signal 424 AND the CA uncorrelated phase-phase signal 428 are asserted. Similarly, AND gate 432 asserts B-phase detection signal D_{B} 452B when both the AB uncorrelated phase-phase signal 424 AND the BC uncorrelated phase-phase signal 426 are asserted. Likewise, AND gate 434 asserts C-phase detection signal D_{C} 452C when both the BC uncorrelated phase-phase signal 426 AND the CA uncorrelated phase-phase signal 428 are asserted.

Accordingly, the uncorrelated phase is found. The uncorrelated phase may determined as experiencing a potential transformer failure. As is discussed furthermore herein, an IED operating to detect potential transformer failures may use the determined uncorrelated phase to assert alarms, modify a display, or even assert a protective action upon determining the uncorrelated phase. In accordance with several embodiments, the IED may be configured to provide further processing of the uncorrelated signal(s) to increase reliability of a potential transformer failure signal.

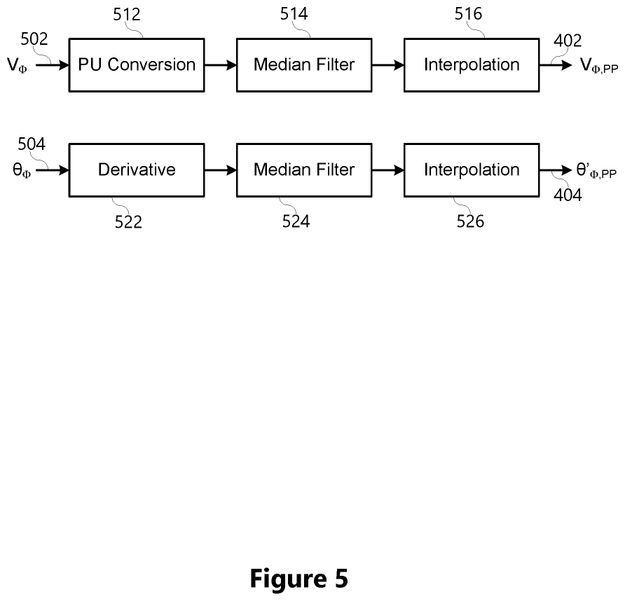

FIG. 5 illustrates an embodiment for determining the pre-processed voltage magnitude signals V_{ϕ,PP} 402 and pre-processed voltage angle signals θ′_{ϕ,PP} 404 that may be used as signals 402A-C and 404A-C of FIG. 4. The phase voltage magnitudes V_{ϕ} 502 are converted into per-unit (pu) values 512. Per-unit conversion may be used to make downstream processing independent of the different voltage levels in a power system. Any frequency deviation from nominal is calculated by taking the derivative 522 of the phase voltage angles θϕ 504. Outliers in measured data that result from communication errors, phasor measurement unit (PMU) synchronization errors, or fast transients are filtered using a median filter 514, 524. Linear interpolation 516, 526 is used to reconstruct missing and bad samples. Accordingly, pre-processed voltage phase magnitude signals V_{ϕ,PP} 402 and the pre-processed voltage angle derivative, θ′_{ϕ,PP} 404 may be calculated and used for determining an uncorrelated phase as separately illustrated.

In various embodiments, PMUs may report phasor estimates at 25, 30, 50, or 60 samples/second. Embodiments using a detection algorithm such as discussed herein may operate at the native sampling rate. Because the potential transformer failure signatures are intermittent and can last for weeks, alarms that are generated at the native PMU data rate can overwhelm operators and engineers. In the postprocessing stage, digital flags are further qualified to avoid false alarms.

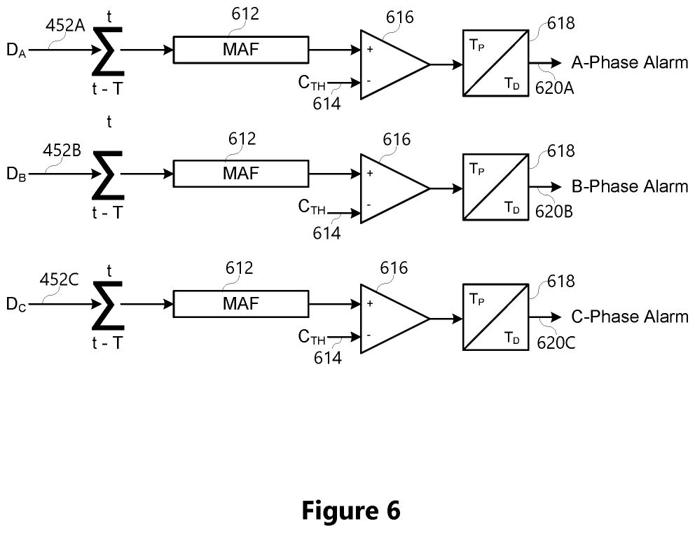

FIG. 6 illustrates a logic diagram that may be used for the postprocessing stage. Digital phase detection signals D_{A} 452A, D_{B} 452B, and D_{C} 452C may be cumulated over a time window (T). The cumulated values are then passed through a moving average filter (MAF) 612. Using both the cumulation and MAF stages together provides advantages over simply averaging a time window. The cumulation stage can significantly reduce the MAF filter length required for satisfactory operation. For example, if the PMU data rate is 30 samples/second, a moving average over a minute requires an MAF of length 1,800. If T equals 1 second, then the MAF length can only be 60. This effectively works to downsample the original signal to 1 sample/second.

Alarm generation for each phase 620A, 620B, 620C may include thresholding. That is, the output of the MAF 612 for each phase may be compared 616 with a predetermined threshold C_{TH} 614. In various embodiments, MAF filter taps can be set so that the output is a detection percentage over all samples in a certain time window (e.g., 1 minute). A pickup/dropout timer 618 may be used for each phase. The alarm pickup time (TP) and the dropout time (TD) can also be predetermined to enhance the alarming process. In addition, time grouping, or hysteresis, can be used to reduce alarms that are due to chattering.

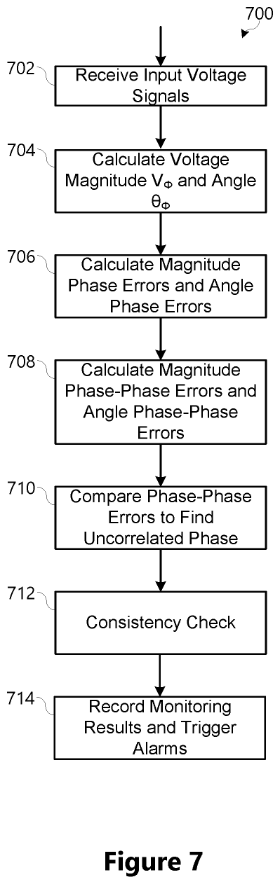

FIG. 7 illustrates a method 700 for detecting incipient failures in a potential transformer using signals therefrom in accordance with several embodiments. The method starts with receiving input voltage signals 702. The input voltage signals may be obtained from phase potential transformers directly, or using intermediate devices such as IEDs, merging units, or the like. The input voltage signals are used to calculate phase voltage magnitudes V_{ϕ} and angles θ_{ϕ} 704. Various embodiments may apply pre-processing to the phase voltage magnitudes V_{ϕ} and angles θ_{ϕ} to produce pre-processed phase voltage signals. The voltage magnitude phase errors and voltage angle phase errors may be calculated 706 as is described herein; and the voltage magnitude phase-phase errors and voltage angle phase-phase errors may also be calculated 708. The voltage magnitude phase-phase errors and voltage angle phase-phase errors may be used to determine one or more uncorrelated phases 710. The uncorrelated phases may correspond with a common phase in the phase-phase pairs of voltage magnitude phase-phase errors and voltage angle phase-phase errors. Such phase may be termed as uncorrelated as it may be uncorrelated with the other of the phases in the multiple-phase electric power delivery system.

The uncorrelated phase may be associated with an incipient potential transformer failure. To facilitate proper alarming and monitoring, a consistency check 712 may be applied to the uncorrelated phase determination. The consistency check 712 may correspond with the post-processing as illustrated in FIG. 6. The method may then record monitoring results and trigger alarms 714 such that operation personnel are made aware of the incipient failure in the potential transformer associated with the indicated phase. Accordingly, personnel may schedule and perform maintenance on the potential transformer, avoiding catastrophic failure and broader system downtime associated with potential transformer failure.

The embodiments presented herein and discussed in association with FIGS. 3-7 may be executed using an IED. The IED may be a protective relay as is illustrated in FIG. 1. In various embodiments, the IED may be embodied as a digital fault recorder that receives signals from the electric power system and provides alarm and other communication services to an operation center. The IED executing the embodiments described herein may be any intelligent electronic device that receives the appropriate signals and may be used to monitor an electric power delivery system. The IED may be, for example, a protective relay, fault recorder, or a computer in an operation or control room.

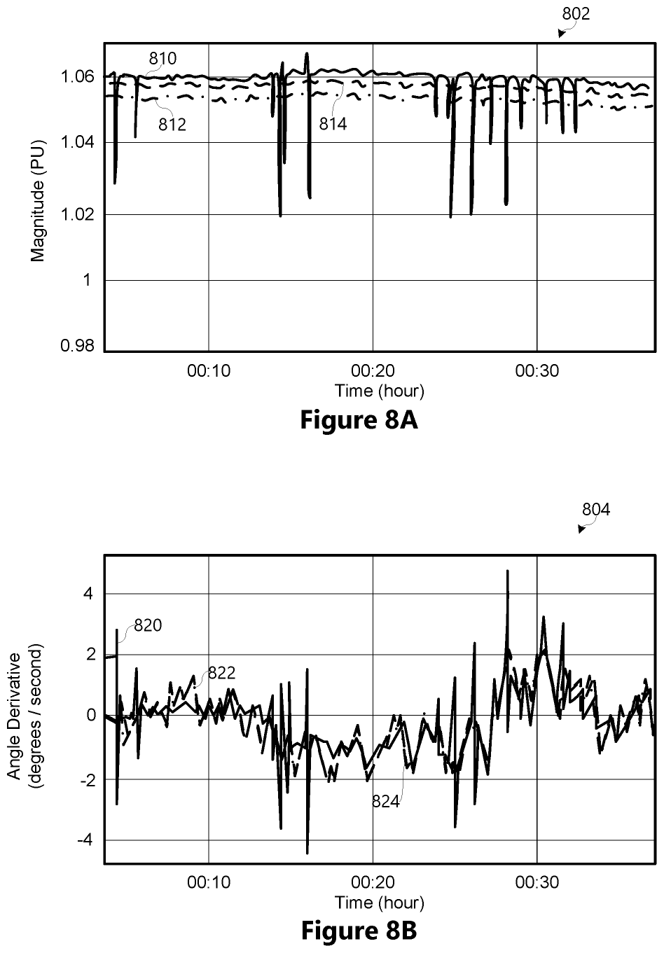

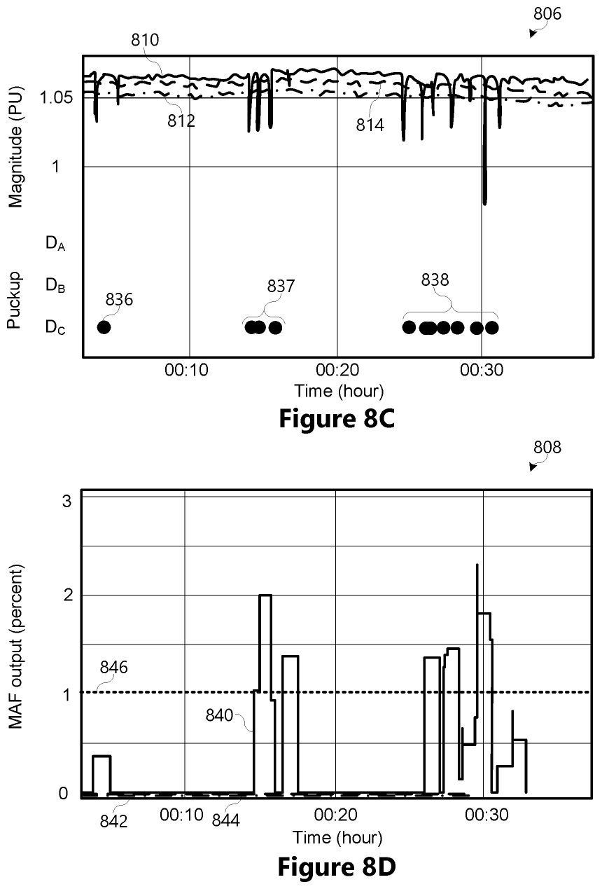

FIGS. 8A, 8B, 8C and 8D illustrate operation of the embodiments described herein performed by an IED for detection of incipient potential transformer failures. The illustrated operation is represented by plots of signals during a time of incipient failures in phase C and outputs from various portions of the embodiments disclosed herein. In particular.

FIG. 8A illustrates a plot 802 of phase A, phase B, and phase C voltage magnitudes (in per-unit) over a time of around 40 minutes. The signals were pre-processed as described herein. For PMU measurements at 30 samples/second, a 5-sample median filter was used. The phase-A voltage magnitude 812 are observed as at just below 1.06 PU and exhibit little variation. Similarly, the phase-B voltage magnitude 814 is illustrated as just below 1.06 PU and exhibit little variation. However, the phase-C magnitude 810 exhibits several excursions below 1.04 PU and reaching 1.02 PU during the captured period. FIG. 8B similarly illustrates a plot 804 of the voltage angle (in degrees/second) of phase A 822, phase B 824 and phase C 820 over the same time period. The angles for phases A and B are somewhat stable, whereas several excursions from nominal (0) may be observed for phase C.

Upon application of the embodiments herein, FIG. 8C illustrates a plot 806 over the same time period, including assertion of the phase detection signals D_{A}, D_{B}, D_{C} (e.g. 452A, 452B, 452C of FIG. 4). As can be seen C-phase detection signal D_{C} is asserted repeatedly 836, 837, 838 corresponding with visible excursions of the per-unit voltage magnitude. In the illustrated embodiment, the voltage magnitude threshold VTH was set at 0.001 PU and the voltage angle threshold θ′_{TH} was set at 0.1 degree/second. An LPF with passband and stopband frequencies of 0.001 and 0.5 Hz, and ripples of 0.02 and 10 dB, respectively, was used as the LPF with IIR (406). An equiripple LPF with passband and stopband frequencies of 1.5 and 2.5 Hz and ripples of 0.02 and 50 dB, respectively was used as the LPF with FIR (408)

FIG. 8D illustrates a plot 808 over a similar time period an output of an alarm after post-processing in accordance with several embodiments described herein. As illustrated, the postprocessing was performed by summing signals over a 1-second time (T−1 second). A 60-tap MAF 612 was used with coefficient values equal to 100/(60*fₛ). The sampling rate was fₛ=30 samples/second. The pickup time T_{P} and dropout time TD of timer 618 were set to 0 seconds and 1 hour, respectively. Alarms were generated with the threshold C_{TH} 614 set to one percent (illustrated as 846). With this setting, an alarm is generated with the failure is detected for one percent of the time, averaged over the last one minute of data obtained. The alarm settings may be configured to reduce the number of alarms generated for each event, so that operators are not overwhelmed. For the illustrated event, alarms were generated only when signals 840 (C-phase) 842 (A-phase) and/or 844 (B-phase) exceeded the threshold 846. As can be seen, only C-phase 840 is illustrated as generating an alarm. Accordingly, incipient potential transformer failures are detected on C-phase only. In various embodiments, a dropout time may be selected to result in a single alarm for each event.

While specific embodiments and applications of the disclosure have been illustrated and described, it is to be understood that the disclosure is not limited to the precise configurations and components disclosed herein. For example, the systems and methods described herein may be applied to an industrial electric power delivery system or an electric power delivery system implemented in a boat or oil platform that may or may not include long-distance transmission of high-voltage power. Accordingly, many changes may be made to the details of the above-described embodiments without departing from the underlying principles of this disclosure. The scope of the present disclosure should, therefore, be determined only by the following claims.

Indeed, the embodiments set forth in the present disclosure may be susceptible to various modifications and alternative forms, specific embodiments have been shown by way of example in the drawings and have been described in detail herein. However, it may be understood that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). For any claims containing elements designated in any other manner, however, it is intended that such elements are not to be interpreted under 35 U.S.C. 112(f).

What is claimed is:

1. A method, comprising:
obtaining phase voltages from each phase of a multiple-phase electric power delivery system by an intelligent electronic device (IED);
calculating voltage magnitudes for each phase from the obtained phase voltages;
calculating voltage angles for each phase from the obtained phase voltages;
calculating voltage magnitude errors for each phase;
calculating voltage angle errors for each phase;
calculating voltage phase-phase errors for each phase pair;
comparing phase-phase errors to determine an uncorrelated phase;
determining an incipient failure signal corresponding with the determined uncorrelated phase; and
issuing a notification indicating the incipient failure and the corresponding phase.

2. The method of claim 1, wherein calculating voltage phase-phase errors comprises calculating voltage magnitude phase-phase errors and voltage angle phase-phase errors.

3. The method of claim 2, wherein comparing phase-phase errors comprises comparing the voltage magnitude phase-phase errors the voltage angle phase-phase errors.

4. The method of claim 3, wherein the uncorrelated phase corresponds with a common phase from the voltage magnitude phase-phase error comparison and the voltage angle phase-phase error comparison.

5. The method of claim 1, further comprising:
pre-processing the voltage magnitudes for each phase to produce pre-processed voltage phase magnitudes;
pre-processing the voltage angles for each phase to produce pre-processed voltage phase angles;
wherein the voltage magnitude errors are calculated using the pre-processed voltage phase magnitudes; and
wherein the voltage angle errors are calculated using the pre-processed voltage phase angles.

6. The method of claim 5, wherein:
pre-processing the voltage magnitudes comprises calculating per-unit voltage magnitudes for each phase; and
pre-processing the voltage angles comprises calculating derivatives of the voltage angles for each phase.

7. The method of claim 1, wherein the method further comprises comparing the phase-phase errors to a predetermined threshold for determination of the uncorrelated phase.

8. The method of claim 1, further comprising calculating a portion of time that the incipient failure signal is present, and issuing the notification only when the portion of time exceeds a predetermined threshold.

9. One or more tangible, non-transitory, computer-readable media comprising instructions that, when executed by a processor of an intelligent electronic device configured to monitor at least a part of an electric power delivery system, cause the processor to:
obtain phase voltages from each phase of a multiple-phase electric power delivery system;
calculate voltage magnitudes for each phase from the obtained phase voltages;
calculate voltage angles for each phase from the obtained phase voltages;
calculate voltage magnitude errors for each phase;
calculate voltage angle errors for each phase;
calculate voltage phase-phase errors for each phase pair;
compare phase-phase errors to determine an uncorrelated phase;
determine an incipient failure signal corresponding with the determined uncorrelated phase; and
issue a notification indicating the incipient failure and the corresponding phase.

10. The one or more computer-readable media of claim 9, wherein calculating voltage phase-phase errors comprises calculating voltage magnitude phase-phase errors and voltage angle phase-phase errors.

11. The one or more computer-readable media of claim 10, wherein the comparing phase-phase errors comprises comparing the voltage magnitude phase-phase errors and comparing the voltage angle phase-phase errors.

12. The one or more computer-readable media of claim 11, wherein the uncorrelated phase corresponds with a common phase from the voltage magnitude phase-phase error comparison and the voltage angle phase-phase error comparison.

13. The one or more computer-readable media of claim 9, comprising instructions that, when executed by the processor, further cause the processor to:
pre-process the voltage magnitudes for each phase to produce pre-processed voltage phase magnitudes;
pre-process the voltage angles for each phase to produce pre-processed voltage phase angles;
wherein the voltage magnitude errors are calculated using the pre-processed voltage phase magnitudes; and
wherein the voltage angle errors are calculated using the pre-processed voltage phase angles.

14. The one or more computer-readable media of claim 13, wherein:
pre-processing the voltage magnitudes comprises calculating per-unit voltage magnitudes for each phase; and
pre-processing the voltage angles comprises calculating derivatives of the voltage angles for each phase.

15. The one or more computer-readable media of claim 9, comprising instructions that, when executed by the processor, further cause the processor to:
compare the phase-phase errors to a predetermined threshold for determination of the uncorrelated phase.

16. The one or more computer-readable media of claim 9, comprising instructions that, when executed by the processor, further cause the processor to:
calculate a portion of time that the incipient failure signal is present, and issue the notification only when the portion of time exceeds a predetermined threshold.

17. An intelligent electronic device, comprising:
processing circuitry;
a communication interface; and,
a memory device comprising instructions that cause the processing circuitry to:
obtain phase voltages from each phase of a multiple-phase electric power delivery system by an intelligent electronic device (IED);
calculate voltage magnitudes for each phase from the obtained phase voltages;
calculate voltage angles for each phase from the obtained phase voltages;
calculate voltage magnitude errors for each phase;
calculate voltage angle errors for each phase;
calculate voltage phase-phase errors for each phase pair;
compare phase-phase errors to determine an uncorrelated phase;
determine an incipient failure signal corresponding with the determined uncorrelated phase; and
issue a notification indicating the incipient failure and the corresponding phase using the communication interface.

18. The intelligent electronic device of claim 17, wherein the memory device further comprises instructions to cause the processing circuitry to:
calculate voltage magnitude phase-phase errors;
calculate voltage angle phase-phase errors;
compare the voltage magnitude phase-phase errors;
compare the voltage angle phase-phase errors; and,
wherein the uncorrelated phase corresponds with a common phase from the voltage magnitude phase-phase error comparison and the voltage angle phase-phase error comparison.

19. The intelligent electronic device of claim 17, wherein the memory device further comprises instructions to cause the processing circuitry to:
pre-process the voltage magnitudes for each phase to produce pre-processed voltage phase magnitudes;
pre-process the voltage angles for each phase to produce pre-processed voltage phase angles;
wherein the voltage magnitude errors are calculated using the pre-processed voltage phase magnitudes; and
wherein the voltage angle errors are calculated using the pre-processed voltage phase angles.

20. The intelligent electronic device of claim 19, wherein:
pre-processing the voltage magnitudes comprises calculating per-unit voltage magnitudes for each phase; and
pre-processing the voltage angles comprises calculating derivatives of the voltage angles for each phase.
